(19) United States
(12) Patent Application Publication
(10) Pub. No.: US 2007/0247237 A1
(43) Pub. Date: Oct. 25, 2007

(54) Technique for reducing capacitance of a switched capacitor array

(75) Inventor: Behnam Mohammadi, Irvine, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/393,898

(22) Filed: Mar. 31, 2006

(51) Int. Cl. H03B 5/12

(52) U.S. Cl. 331/36 C

(57) ABSTRACT

A circuit reducing the capacitance of a switched capacitor array by mitigating switch capacitance. Reducing the effect of switch capacitance increases the frequency range of an inductor-capacitor tank containing the switched capacitor array. A pull-up circuit is coupled between a voltage source and a node. A switched capacitor and a switch are coupled to the node. The pull-up circuit biases the switch to reduce switch junction capacitance when the switch is off. In an example, a pull-up resistor is coupled between the node and a voltage source to bias the switch. In another example, a pull-up switch and pull-up resistor are coupled between the node and a voltage source to bias the switch.

### FIELD OF THE INVENTION

The present invention is generally directed to switched capacitor arrays. More particularly, the invention relates to an apparatus and method for reducing capacitance of a switched capacitor array.

### BACKGROUND OF THE INVENTION

FIG. 1 shows a block diagram of a tuned voltage controlled oscillator (VCO) 100. A tuned VCO 100 includes a tuned inductor-capacitor (LC) network or tuned tank 102 and an active circuit 104 that uses positive feedback (FB₁) 106 and (FB₂) 108 to compensate for tuned tank 102 loss. Some VCOs 100 also include an optional bias network 110 for biasing. In FIG. 1, bias is provided from the optional bias network 110 via lines (B₁) 112 and (B₂) 114. There are typically two main input signals that are input to the tuned tank 102 that control the VCO 100. The first input signal is the control voltage (V_{ctrl}) 116, which is an analog signal that provides fine tuning by continuously controlling VCO 100 output frequency. The second input signal is an N-bit digital tuning signal 118, carried over n-conductors 120, which is used for discrete control of VCO 100 output frequency. The N-bit digital tuning signal 118 is used to obtain large variations in VCO 100 center frequency in order to coarsely adjust frequency to cover different frequency bands and channels for a given application. The N-bit digital tuning signal 118 can be used for channel selection. The differential VCO 100 in FIG. 1 provides a differential output (O₁, O₂) 122, 124. In the case of a single-ended VCO, a single output is provided.

FIG. 2 shows an example of a schematic of a negative resistance VCO 200. The invention is not limited to the VCO shown in FIG. 2. The tank 202 in the VCO 200 includes two varactors 204, 206, an N-bit tuning capacitor array 208 and an inductor 210. A control voltage 212, drives the varactors 204, 206 for continuous tuning of the VCO 200 center frequency. An N-bit digital tuning signal 214, controls an N-bit capacitor array 208 to obtain digital control of the VCO 200 center frequency. In tank 202, it is easier to vary capacitance than inductance, thus tank control is typically effected by controlling capacitance. The tank in FIG. 2 provides a differential output 216, 218. An active block 220 in the VCO includes a cross-coupled transistor pair 222, 224 that oscillate at the resonant frequency of the tank circuit 202. The cross-coupled transistor pair 222, 224 produces negative resistance to compensate for tank 202 loss. Capacitors are switched-in or switched-out of the capacitor array 208 for coarse frequency tuning, and the control voltage of the varactors 204 and 206 is tuned for fine frequency tuning. The bias network 226 in the VCO 200 is a current mirror that includes transistors 228, 230 and a reference current source 232 that provides bias for transistors 222 and 224. The reference current source 232 can be a bandgap source.

FIG. 3 illustrates a conventional N-bit tuning capacitor array 300 that is an example of the N-bit capacitor array 208. The tuning capacitor array 300 includes two N-bit arrays 302A, B of single-ended switched capacitors 304A, B, . . . , Y. Each switched capacitor 304 is coupled to a switching transistor 306A, B, . . . , Y for switching the switched capacitor 304 on and off. The switched capacitor 304 and switching transistor 306 in the switched capacitor array 302 are typically scaled in a binary fashion. However, the scaling can generally be done in any fashion. The switching transistor 306 is controlled by an N-bit digital tuning signal 308A, B, . . . , N. In the conventional implementation of a switched capacitor array 302 as shown in FIG. 3, a junction capacitance at a drain of the switching transistor 306 causes a non-zero capacitance value of the switching transistor 306 when the switching transistor 306 is off. Thus, an effective “off” capacitance (C_{effn}_{_{—}}_{off}) of each switched capacitor 304 in the switched capacitor array 302 is given by a series combination of that switched capacitor's 304 capacitance (Cₙ) and it's respective switching transistor's 306 junction capacitance (C_{jdn}) as follows:

$${C}_{effn\_off} = \frac{{C}_{n} \times {C}_{jdn}}{{C}_{n} + {C}_{jdn}}$$

where Cₙ is the switched capacitor's 304 capacitance of the n^{th} bit and C_{jdn} is the drain junction capacitance of the n^{th} bit. The non-zero effective capacitance of the switched capacitor 304 provides capacitance to the tank 102. This additional capacitance reduces the upper frequency of the VCO 100 thereby decreasing the overall tuning range because tank 102 frequency is inversely proportional to tank 102 capacitance.

The non-zero effective capacitance of transistor 306 reduces tuning range of the VCO and reduces margin to compensate for part-to-part variations in integrated circuit manufacturing and packaging processes as well as circuit modeling inaccuracies.

FIG. 4 shows a schematic of a differential implementation of an N-bit tuning capacitor array 400. A differential switching transistor 402A, B, . . . , N is used in each branch to switch the capacitors 404A, B, . . . , N; 406A, B, . . . , N. In FIG. 4, transistors 408A, B . . . , N; 410A, B, . . . , N create a path to ground and thus define a voltage at a plate of their respective capacitors 404, 406 when the differential switching transistor 402 is conducting. Transistors 402, 408, and 410 are actuated by an N-bit digital tuning signal 412A, B, . . . , N.

When transistors 402, 408, and 410 are not conducting, a junction capacitance at the respective drains of transistors 402, 408, and 410 causes a non-zero capacitance value of each transistor 402, 408, and 410. The non-zero effective capacitance of the switched capacitors 404 and 406 due to the non-zero capacitance value of transistors 402, 408, and 410 increases capacitance of the switched capacitor array 400. This additional capacitance reduces the upper frequency of a VCO including the switched capacitor array 400 thereby decreasing the overall VCO tuning range.

Accordingly, what is needed is an invention that overcomes the shortcomings noted above.

### BRIEF SUMMARY OF THE INVENTION

A circuit reducing switched capacitor array capacitance by mitigating switching transistor junction capacitance. Reducing switching transistor junction capacitance increases LC tank frequency range. A pull-up circuit is coupled between a voltage source and a node. A switched capacitor and a switching transistor are coupled to the node. The pull-up circuit biases the switching transistor to reduce junction capacitance when the switching transistor is off. In an example, a pull-up resistor is coupled between the node and a voltage source to bias the switching transistor. In another example, a pull-up transistor and a pull-up resistor are coupled between the node and a voltage source to bias the switching transistor.

Further embodiments, features, and advantages of the present inventions, as well as the structure and operation of the various embodiments of the present invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

In the drawings:

FIG. 1 illustrates a block diagram of a tuned voltage-controlled oscillator;

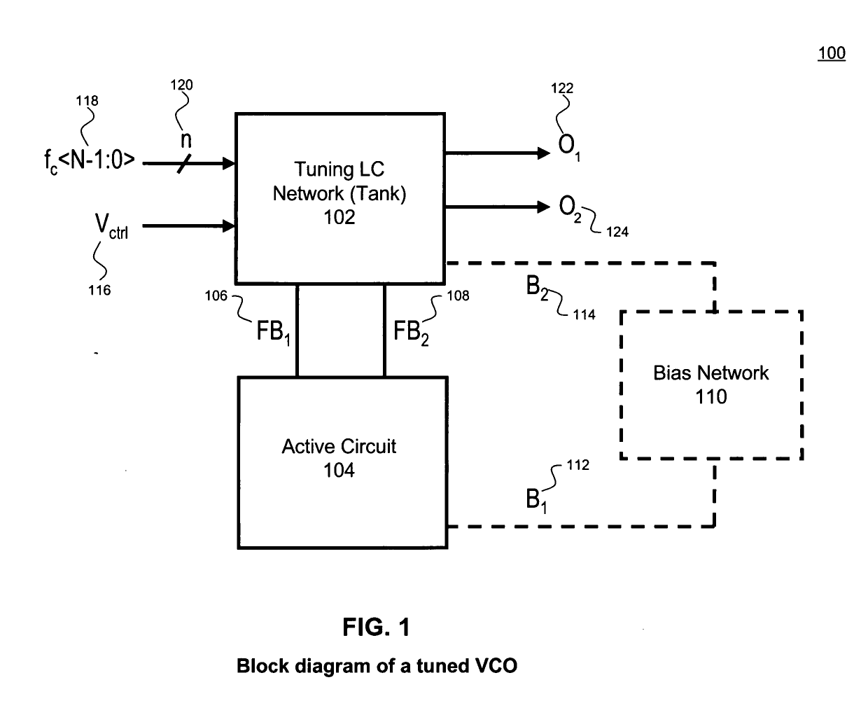

FIG. 2 illustrates a schematic of a negative-resistance tuned voltage controlled oscillator;

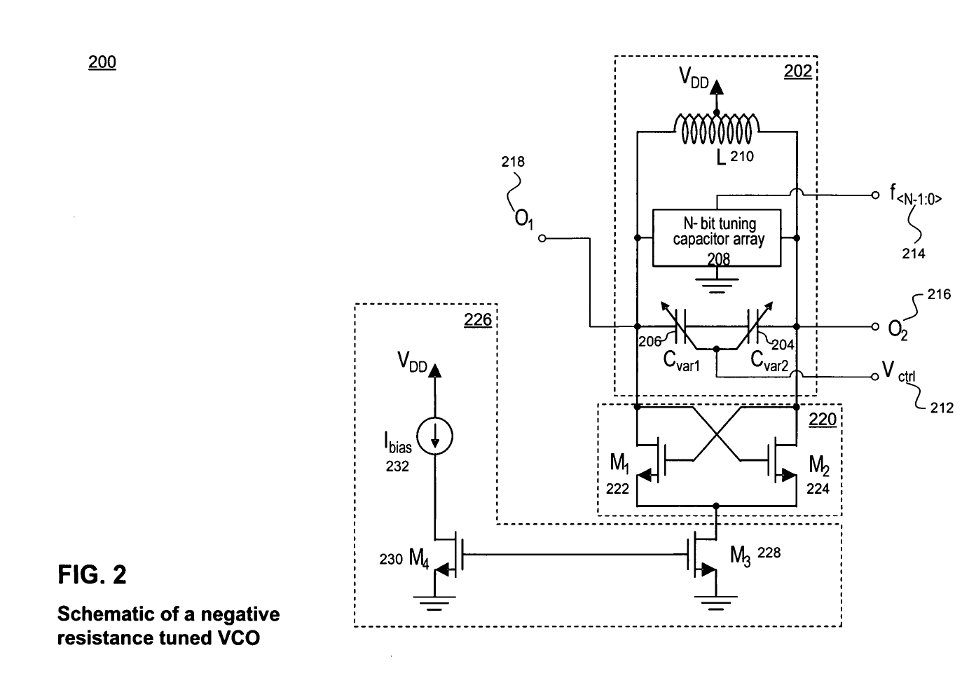

FIG. 3 illustrates a schematic of an N-bit tuning capacitor array in a single-ended implementation;

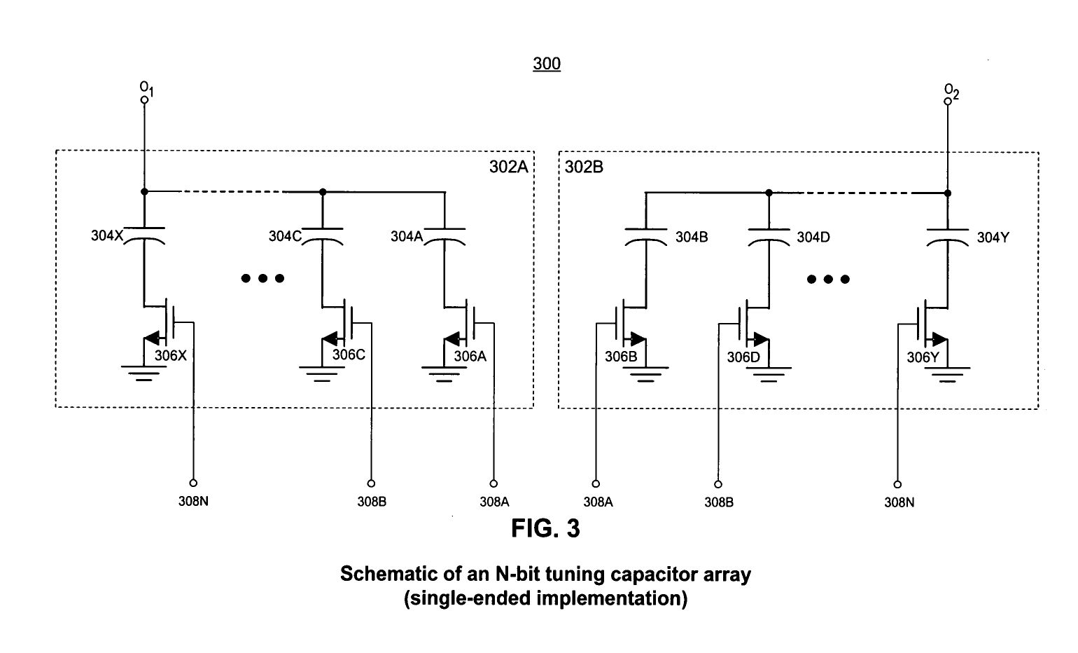

FIG. 4 illustrates a schematic of an N-bit tuning capacitor array in a differential implementation;

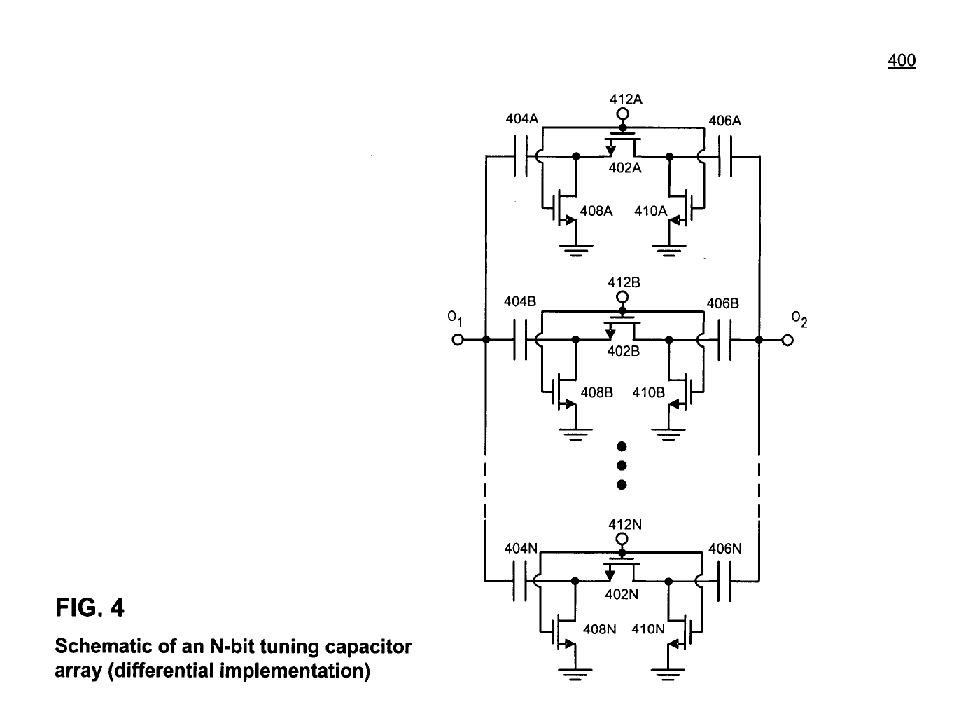

FIG. 5 illustrates a schematic of an N-bit tuning capacitor array with extended tuning range in a single-ended implementation;

FIG. 6 illustrates another schematic of an N-bit tuning capacitor array with extended tuning range in a single-ended implementation;

FIG. 7 illustrates a schematic of an N-bit tuning capacitor array with extended tuning range in a differential implementation;

FIG. 8 illustrates another schematic of an N-bit tuning capacitor array with extended tuning range in a differential implementation; and

FIG. 9 illustrates a method for reducing capacitance of a switched capacitor array.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

A circuit reduces capacitance of a switched capacitor array by mitigating switching transistor junction capacitance. Arrays of switched capacitors are commonly used in circuits such as, for example, an inductor-capacitor (LC) tank circuit. In examples, a switched capacitor array is part of a tank circuit, tuned tank circuit, voltage controlled oscillator, transmitter, and/or receiver.

As used herein, the switched capacitor array includes, and is not limited to, an N-bit tuning capacitor array. In an example, the switched capacitor array comprises at least one capacitor and a switch. A voltage source includes, and is not limited to, an earth ground, a floating ground, a positive voltage source, and a negative voltage source. A switch includes, and is not limited to, a semiconductor switch, a transistor, a field effect transistor (FET), and a bipolar junction transistor (BJT). An array input includes, and is not limited to, a conductive element that couples a control conductor for controlling a capacitor array to the capacitor array.

Within a switched capacitor array, a switch is used to switch a capacitor into and out of the switched capacitor array to vary capacitance of the switched capacitor array. Some switches, such as transistors, have a drain to body junction capacitance (C_{jdn}), also known as drain to substrate capacitance, present when the transistor is off or not conducting. In an example, the drain to body junction capacitance is reduced to lower the switched capacitor array capacitance. Mitigating junction capacitance increases a frequency range of an LC tank including the switched capacitor array. From the equation:

$${C}_{effn\_off} = \frac{{C}_{n} \times {C}_{jdn}}{{C}_{n} + {C}_{jdn}}$$

an effective capacitance (C_{effn}_{_{—}}_{off}) when the transistor is off approaches zero as the drain to body junction capacitance (C_{jdn}) of a switching transistor is reduced and capacitance (Cₙ) of an N-th bit capacitor remains constant. This invention reduces C_{jdn} to increase the LC tank's tuning range. Increasing the tuning range of an LC tank that is part of a voltage-controlled-oscillator (VCO) increases the VCO's frequency range. The switched capacitor array in the invention is not limited to use in the VCO. In examples, the switched capacitor array is part of, and not limited to use in, a tank circuit, a tuned tank circuit, a processor, a voltage controlled oscillator, a transmitter, and/or a receiver.

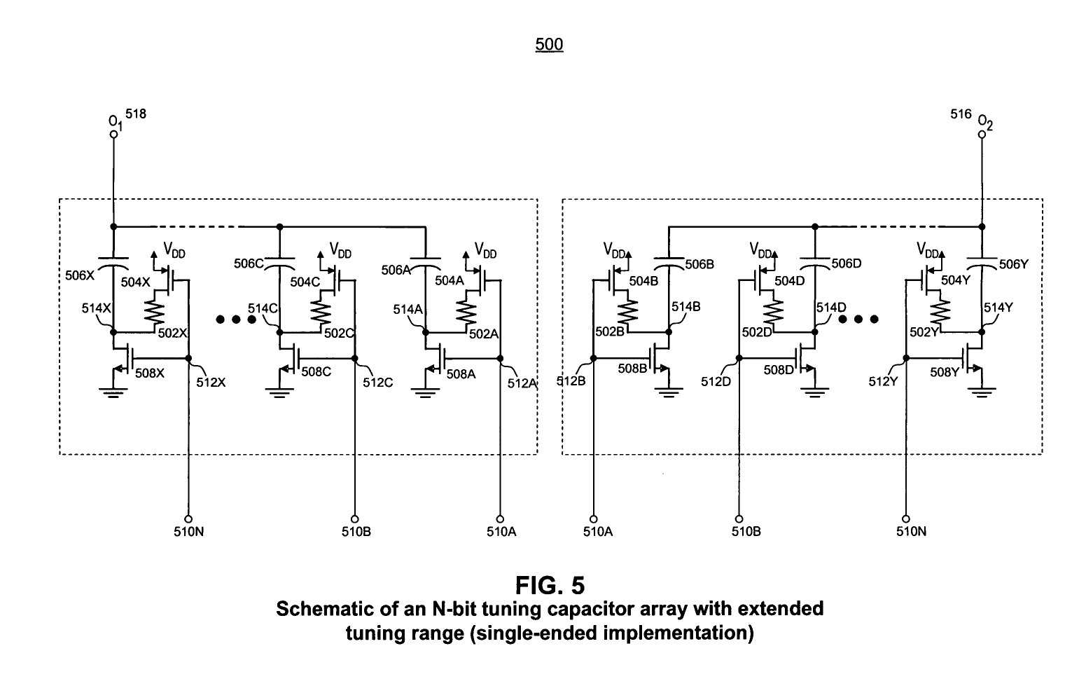

FIG. 5 illustrates a schematic of an N-bit tuning capacitor array 500 with extended tuning range in a single-ended configuration with a first output 518 and a second output 516 according to an example. A switching transistor 508A, B, . . . , Y is coupled to a switched capacitor 506A, B, . . . , Y. The switching transistor 508 provides a switched path to ground via a first node 514A, B, . . . , Y for a first plate of the switched capacitor 506. The second plate of the switched capacitor 506 is coupled to an output 516, 518. The gate of the switching transistor 508 is coupled to an N-bit digital tuning signal 510A, B, . . . , N. In another example, the switching transistor 508 provides a switched path to a voltage source via the first node 514 for the first plate of the switched capacitor 506.

In FIG. 5, a pull-up resistor 502A, B, . . . , Y and a pull-up transistor 504A, B, . . . , Y bias a drain of the switching transistor 508 with the voltage source via the first node 514 to reduce a drain to body junction capacitance of the switching transistor 508. In an example, the pull-up resistor 502 with large resistance relative to the off impedance of the switching transistor 508. The gate of the pull-up transistor 504 and the gate of the switching transistor 508 are coupled via a second node 512A, B, . . . , Y to the N-bit tuning signal 510.

In an example, the pull-up resistor 502, the pull-up transistor 504, and the switched capacitor 506 are scaled to obtain equal time constants for each bit in the capacitor array 500. This preserves the switched capacitor 506 scaling in an off state.

In an example, circuit operation is as follows. The switching transistor 508 switches the switched capacitor 506 into and out of the N-bit tuning capacitor array 500. When the switching transistor 508 conducts, the switched capacitor 506 is switched into the N-bit tuning capacitor array 500, thus increasing the capacitance of the N-bit tuning capacitor array 500. When the switching transistor 508 does not conduct, the switched capacitor 506 is switched out of the N-bit tuning capacitor array 500, thus decreasing the capacitance of the N-bit tuning capacitor array 500. When the switching transistor 508 conducts, the switching transistor 508 permits a voltage to be defined via a first node 514 at a plate of the switched capacitor 506. In an example, a voltage defined at a plate of a switched capacitor 506 via the first node 514 is ground. In another example, a voltage defined at a plate of the switched capacitor 506 via the first node 514 is provided by a voltage source.

The drain to body junction capacitance of the switching transistor 508 is reduced when the switching transistor's 508 drain to body bias voltage is increased. When the switching transistor 508 is not conducting, the pull-up transistor 504 conducts and raises the drain to body bias voltage of the switching transistor 508 to a voltage source via the first node 514 and the pull-up resistor 502 to minimize the switching transistor's 508 drain to body junction capacitance. When the switching transistor 508 is conducting, the pull-up transistor 504 need not conduct because drain to body junction capacitance of the switching transistor 508 does not reduce tuning range when the switching transistor 508 is conducting. Conduction of the switching transistor 508 and the pull-up transistor 504 is controlled by the N-bit digital tuning signal 510.

The reduction of a switching transistor's 508 drain to body junction capacitance increases an upper frequency of a VCO including an LC tank containing the N-bit tuning capacitor array 500 thereby increasing the VCO's tuning range.

In an example, when the switching transistor 508 is not conducting, the pull-up transistor 504 conducts. Turning off the switching transistor 508 and turning on the pull-up transistor 504 to bias the switching transistor 508 are steps that are performed substantially simultaneously because the switching transistor 508 and the pull-up transistor 504 are controlled by a common N-bit digital tuning signal 510 via the second node 512. Turning on the switching transistor 508 and turning off the pull-up transistor 504 to bias the switching transistor 508 are also steps that are performed substantially simultaneously because the switching transistor 508 and the pull-up transistor 504 are controlled by the N-bit digital tuning signal 510 via the second node 512.

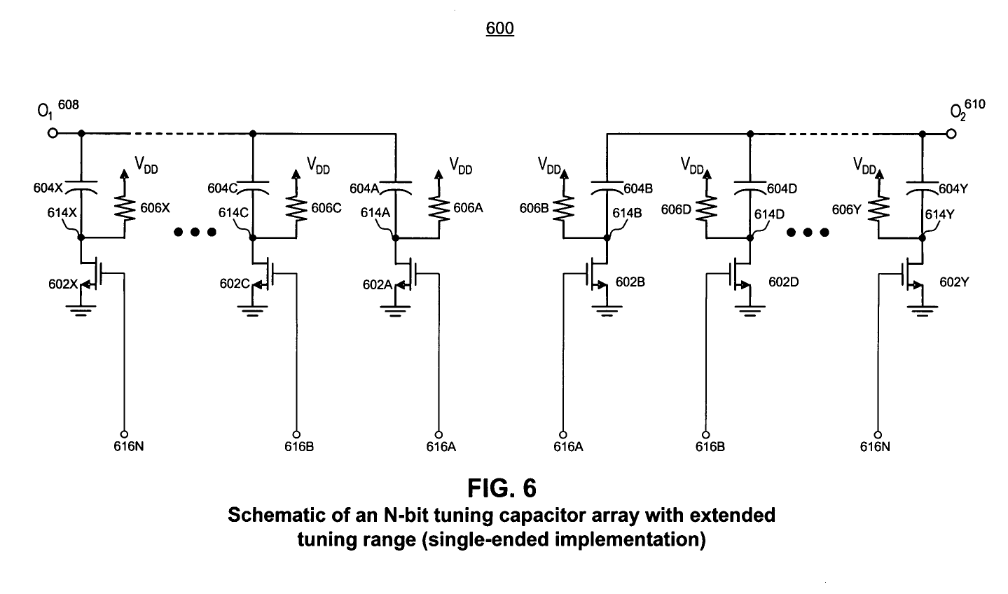

FIG. 6 illustrates a schematic of an N-bit tuning capacitor array 600 with extended tuning range in a single-ended configuration with a first output 608 and a second output 610 according to another example. In this example, a switching transistor 602A, B, . . . , Y is coupled to a switched capacitor 604A, B, . . . , Y. The switching transistor 602 provides a switched path to ground via a node 614 for a first plate of the switched capacitor 604. A second plate of the switched capacitor 604 is coupled to an output 608, 610. A gate of the switching transistor 602 is coupled to a corresponding N-bit digital tuning signal 616A, B, . . . , N. In an example, the switching transistor 602 provides a switched path to a voltage source via a node 614A, B, . . . , Y for a first plate of the switched capacitor 604.

In the example in FIG. 6, a pull-up resistor 606A, B, . . . , Y biases a drain of the switching transistor 602 with a voltage source via the node 614 to reduce a capacitance of the N-bit tuning capacitor array 600. In an example, the pull-up resistor 606 has a large resistance relative to an off impedance of the switching transistor 602. A large pull-up resistor 606 also minimizes power dissipation when the switching transistor 602 is conducting.

In an example, the pull-up resistor 606 and the switched capacitor 604 are scaled to obtain equal time constants for each bit in the N-bit tuning capacitor array 600. This preserves the switched capacitor 604 scaling in an off state.

In an example, circuit operation is as follows. The switching transistor 602 switches the switched capacitor 604 into and out of the N-bit tuning capacitor array 600. When the switching transistor 602 conducts, the switched capacitor 604 is switched into the N-bit tuning capacitor array 600, thus increasing the capacitance of the N-bit tuning capacitor array 600. When the switching transistor 602 does not conduct, the switched capacitor 604 is switched out of the N-bit tuning capacitor array 600, thus decreasing the capacitance of the N-bit tuning capacitor array 600. When the switching transistor 602 conducts, the switching transistor 602 permits a voltage to be defined via the node 614 at a plate of the switched capacitor 604. In an example, a voltage defined at a plate of the switched capacitor 604 via the node 614 is ground. In another example, the voltage defined at the plate of the switched capacitor 604 via the node 614 is provided by a voltage source other than ground.

A drain to body junction capacitance of a switching transistor 602 is reduced when the switching transistor's 602 drain to body bias voltage is increased. When the switching transistor 602 is not conducting, the pull-up resistor 606 raises the drain to body bias voltage of the switching transistor 602 to a voltage source via the node 614 to minimize the switching transistor's 602 drain to body junction capacitance. Conduction of the switching transistor 602 is controlled by a N-bit digital tuning signal 616.

In an example, reduction of the switching transistor's 602 drain junction capacitance increases an upper frequency of a VCO including an LC tank containing the N-bit tuning capacitor array 600 thereby increasing the VCO's tuning range.

In an example, turning off the switching transistor 602 and raising a drain to body bias of the switching transistor 602 are steps that are performed substantially simultaneously because the switching transistor 602 and the pull-up resistor 606 are coupled via the node 614.

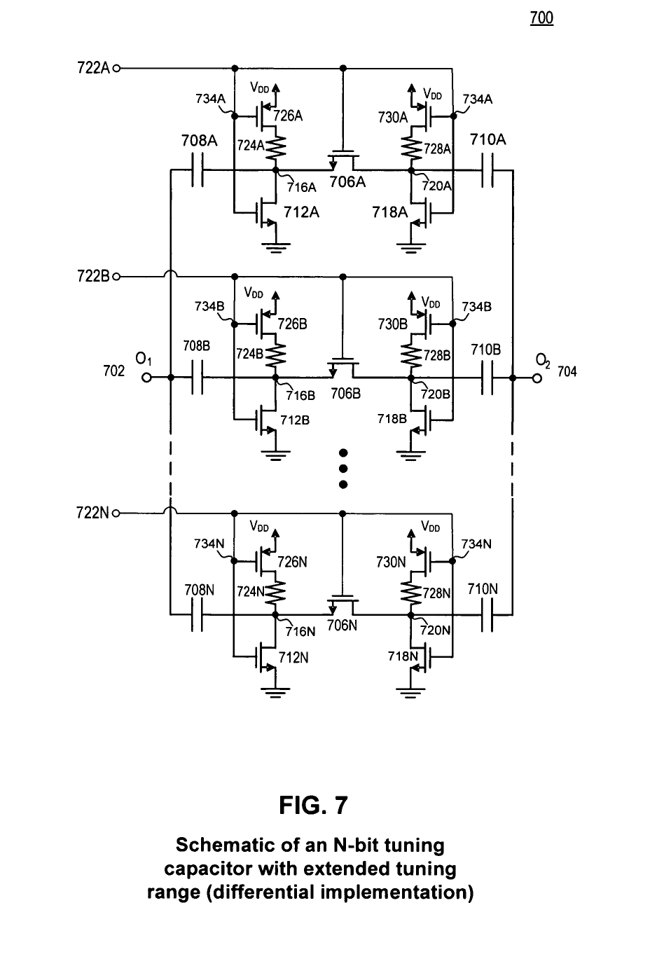

FIG. 7 illustrates a schematic of an N-bit tuning capacitor array 700 with extended tuning range according to another example where a differential switching scheme is implemented with a first output 702 and a second output 704. In this example, a differential switching transistor 706A, B, . . . , N is coupled to both a first switched capacitor 708A, B, . . . , N and a second switched capacitor 710A, B, . . . , N. A first switching transistor 712A, B, . . . , N provides a switched path to ground via a first node 716A, B, . . . , N for a first plate of the first switched capacitor 708. The second plate of the first switched capacitor 708 is coupled to the first output 702. A second switching transistor 718A, B, . . . , N provides a switched path to ground via a second node 720A, B, . . . , N for a first plate of the second switched capacitor 710. The second plate of the second switched capacitor 710 is coupled to the second output 704. The gates of the differential switching transistor 706, the first switching transistor 712, and the second switching transistor 718 are coupled to a common N-bit digital tuning signal 722A, B, . . . , N.

A first pull-up resistor 724A, B, . . . , N and a first pull-up transistor 726A, B, . . . , N bias a drain of the first switching transistor 712 at a voltage source via the first node 716 to reduce a capacitance of the N-bit tuning capacitor array 700. A second pull-up resistor 728A, B, . . . , N and a second pull-up transistor 730A, B, . . . , N bias the drain of the second switching transistor 718 at the voltage source via the second node 720 to reduce the capacitance of the N-bit tuning capacitor array 700. In an example, both the first pull-up resistor 724 and the second pull-up resistor 728 have a large resistance relative to the off impedance of the differential switching transistor 706, the first switching transistor 712, and the second switching transistor 718. A gate of the first pull-up transistor 726 and a gate of the second pull-up transistor 730 are coupled via a third node 734A, B, . . . , N to an N-bit digital tuning signal 722.

In an example, the first pull-up resistor 724, the first pull-up transistor 726, the second pull-up resistor 728, the second pull-up transistor 730, the first switched capacitor 708, and the second switched capacitor 710 are scaled to obtain equal time constants for each bit in an N-bit tuning capacitor array 700. This preserves capacitor scaling in an off state.

In an example, circuit operation is as follows. The differential switching transistor 706 switches the first switched capacitor 708 and the second switched capacitor 710 into and out of the N-bit tuning capacitor array 700. When the differential switching transistor 706 conducts, the first switched capacitor 708 and the second switched capacitor 710 are switched into the N-bit tuning capacitor array 700, thus increasing the capacitance of the N-bit tuning capacitor array 700. When the differential switching transistor 706 does not conduct, the first switched capacitor 708 and the second switched capacitor 710 are switched out of the N-bit tuning capacitor array 700, thus decreasing the capacitance of the N-bit tuning capacitor array 700.

When the differential switching transistor 706 conducts, the first switching transistor 712 and the second switching transistor 718 also both conduct. When the differential switching transistor 706 does not conduct, the first switching transistor 712 and the second switching transistor 718 also do not conduct. When the first switching transistor 712 conducts, the first switching transistor 712 defines a voltage via the node 716 at a plate of the first switched capacitor 708. When the second switching transistor 718 conducts, the second switching transistor 718 defines a voltage via the node 720 at a plate of the second switched capacitor 710. In an example, the voltage defined at the node 716 and the node 720 is ground.

Drain to body junction capacitances, also known as drain to substrate junction capacitances, of the differential switching transistor 706, the first switching transistor 712, and the second switching transistor 718 are reduced when drain to body bias voltages of the differential switching transistor 706, the first switching transistor 712, and the second switching transistor 718 are increased. When the differential switching transistor 706, the first switching transistor 712, and the second switching transistor 718 are not conducting, the first pull-up transistor 726 and the second pull-up transistor 730 conduct and raise the drain to body bias voltages of the differential switching transistor 706, the first switching transistor 712, and the second switching transistor 718 to a voltage source via the first node 716, the second node 720, the first pull-up resistor 724, and the second pull-up resistor 728. Thus, the drain junction capacitances of the differential switching transistor 706, the first switching transistor 712, and the second switching transistor 718 are reduced.

When the differential switching transistor 706, the first switching transistor 712, and the second switching transistor 718 are conducting, the first pull-up transistor 726 and the second pull-up transistor 730 do not conduct because drain junction capacitance does not reduce tuning range when the switching transistors are conducting. Conduction of the differential switching transistor 706, the first switching transistor 712, the second switching transistor 718, the first pull-up transistor 726, and the second pull-up transistor 730 is controlled by an N-bit digital tuning signal 722.

In an example, reduction of the drain junction capacitances of the differential switching transistor 706, the first switching transistor 712, and the second switching transistor 718 increases an upper frequency of a VCO including the N-bit tuning capacitor array 700, thereby increasing the VCO's tuning range.

In an example, the differential switching transistor 706, the first switching transistor 712, and the second switching transistor 718 are switched identically as a first group by a common N-bit digital tuning signal 722. The first pull-up transistor 726 and the second pull-up transistor 730 are switched identically as a second group by the common N-bit digital tuning signal 722. When the differential switching transistor 706, the first switching transistor 712, and the second switching transistor 718 are conducting, the first pull-up transistor 726 and the second pull-up transistor 730 do not conduct. Conversely, when the differential switching transistor 706, the first switching transistor 712, and the second switching transistor 718 are not conducting, the second pull-up transistor 730 and the first pull-up transistor 726 do conduct.

In an example, turning off the differential switching transistor 706, the first switching transistor 712, and the second switching transistor 718 while turning on the pull-up transistor 730 and the first pull-up transistor 726 to bias the first switching transistor 712 and the second switching transistor 718 are steps that are performed substantially simultaneously because the differential switching transistor 706, the first switching transistor 712, the second switching transistor 718, the pull-up transistor 730, and the first pull-up transistor 726 are controlled by the N-bit digital tuning signal 722 via a node 734. In another example, turning on the differential switching transistor 706, the first switching transistor 712, and the second switching transistor 718 while turning off the pull-up transistor 730 and the first pull-up transistor 726 to bias the differential switching transistor 706, the first switching transistor 712 and the second switching transistor 718 are steps that are performed substantially simultaneously because the differential switching transistor 706, the first switching transistor 712, the second switching transistor 718, the pull-up transistor 730, and the first pull-up transistor 726 are controlled by the N-bit digital tuning signal 722 via the node 734.

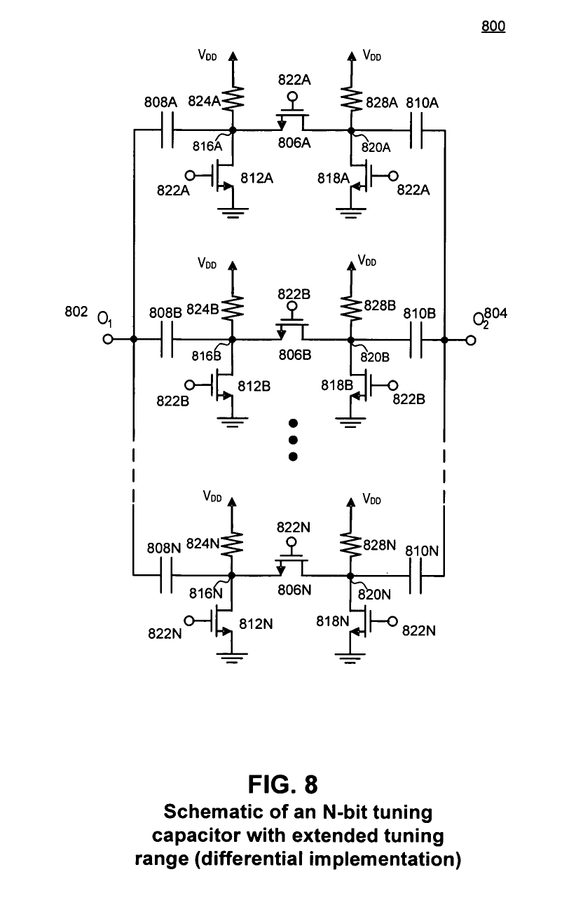

FIG. 8 illustrates a schematic of an N-bit tuning capacitor array 800 with extended tuning range according to another example where a differential switching scheme is implemented with a first output 802 and a second output 804. In this example, a differential switching transistor 806A, B, . . . , N is coupled to both a first switched capacitor 808A, B, . . . , N and a second switched capacitor 810A, B, . . . , N. A first switching transistor 812A, B, . . . , N provides a switched path to ground via a first node 816A, B, . . . , N for a first plate of the first switched capacitor 808. The second plate of the first switched capacitor 808 is coupled to the first output 802. A second switching transistor 818A, B, . . . , N provides a switched path to ground via a second node 820A, B, . . . , N for a first plate of the second switched capacitor 810. The second plate of the second switched capacitor 810 is coupled to the second output 804. The gates of the differential switching transistor 806, the first switching transistor 812, and the second switching transistor 818 are coupled to a common N-bit digital tuning signal 822A, B, . . . , N.

A first pull-up resistor 824A, B, . . . , N biases a drain of the first switching transistor 812 at a voltage source via the first node 816 to reduce a capacitance of the N-bit tuning capacitor array 800. A second pull-up resistor 828A, B, . . . , N biases the drain of the second switching transistor 818 and the differential switching transistor 806 at the voltage source via the second node 820 to reduce the capacitance of the N-bit tuning capacitor array 800. In an example, the first pull-up resistor 824 and the second pull-up resistor 828 have a large resistance relative to the off impedance of the differential switching transistor 806, the first switching transistor 812, and the second switching transistor 818 to minimize power dissipation.

In an example, the first pull-up resistor 824, the second pull-up resistor 828, the first switched capacitor 808, and the second switched capacitor 810 are scaled to obtain equal time constants for each bit in the N-bit tuning capacitor array 800. This scaling preserves capacitor scaling in an off state.

In an example, circuit operation is as follows. The differential switching transistor 806 switches the first switched capacitor 808 and the second switched capacitor 810 into and out of the N-bit tuning capacitor array 800. When the differential switching transistor 806 conducts, the first switched capacitor 808 and the second switched capacitor 810 are switched into the N-bit tuning capacitor array 700, thus increasing the capacitance of the N-bit tuning capacitor array 800. When the differential switching transistor 806 does not conduct, the first switched capacitor 808 and the second switched capacitor 810 are switched out of the N-bit tuning capacitor array 800, thus decreasing the capacitance of the N-bit tuning capacitor array 800.

When the differential switching transistor 806 conducts, the first switching transistor 812 and the second switching transistor 818 also both conduct. When the differential switching transistor 806 does not conduct, the first switching transistor 812 and the second switching transistor 818 both do not conduct. When the first switching transistor 812 conducts, the first switching transistor 812 defines a voltage via the node 816 at a plate of the first switched capacitor 808. When the second switching transistor 818 conducts, the second switching transistor 818 defines a voltage via the node 820 at a plate of the second switched capacitor 810. In an example, the voltage defined at the node 816 and the node 820 is ground.

Drain to body junction capacitances of the differential switching transistor 806, the first switching transistor 812, and the second switching transistor 818 are reduced when drain to body bias voltages of the differential switching transistor 806, the first switching transistor 812, and the second switching transistor 818 are increased. When the differential switching transistor 806, the first switching transistor 812, and the second switching transistor 818 are not conducting, the first pull-up resistor 824 and the second pull-up resistor 828 raise the drain to body bias voltages of the differential switching transistor 806, the first switching transistor 812, and the second switching transistor 818 to a voltage source via the first node 816 and the second node 820. Thus, the drain junction capacitances of the differential switching transistor 806, the first switching transistor 812, and the second switching transistor 818 are reduced. Conduction of the differential switching transistor 806, the first switching transistor 812, and the second switching transistor 818 are reduced is controlled by the N-bit digital tuning signal 822.

In an example, reduction of drain to body junction capacitances of the differential switching transistor 806, the first switching transistor 812, and the second switching transistor 818 increases an upper frequency of a VCO including the N-bit tuning capacitor array 800 thereby increasing the VCO's tuning range.

In an example, turning off the differential switching transistor 806, the first switching transistor 812, and the second switching transistor 818; raising a drain bias of the first switching transistor 812; and raising a drain bias of the second switching transistor 818 are steps that are performed substantially simultaneously because the differential switching transistor 806, the first switching transistor 812, and the second switching transistor 818 are coupled by their respective first node 816 and second node 820. In an example, turning on the differential switching transistor 806, the first switching transistor 812, and the second switching transistor 818; raising the drain bias of the first switching transistor 812; and raising the drain bias of the second switching transistor 818 are steps that are performed substantially simultaneously because the differential switching transistor 806, the first switching transistor 812, and the second switching transistor 818 are coupled respectively by the first node 816 and the second node 820.

In addition to the benefits listed above, this invention lowers a phase noise of a VCO because the invention permits an increased switch size in an N-bit tuning capacitor array without tuning range reduction. The increased switch size provides a higher tank quality factor due to reduced switch resistance. The higher tank quality factor provides better phase noise performance in the tuning range of the VCO.

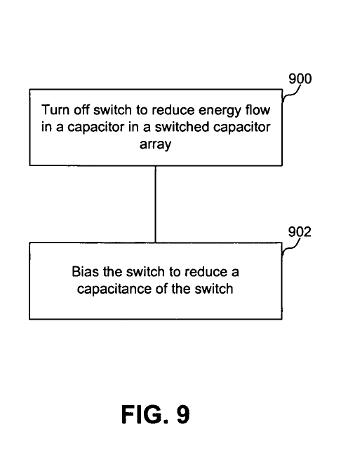

A method for reducing capacitance of a switched capacitor array comprises at least the steps as illustrated in FIG. 9. At a step 900, a first switch is turned off to reduce energy flow in a capacitor in a switched capacitor array. At a step 902, the first switch is biased to reduce a capacitance of the first switch. In an example, the first switch capacitance that is reduced is a drain to source capacitance. In other examples, a method for reducing capacitance of a switched capacitor array includes additional steps and features. In another example, a step 902 includes actuating a second switch to control the biasing of the first switch. In yet another example, turning off a first switch and biasing a first switch is performed substantially simultaneously.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

What is claimed is:

1. A circuit for reducing capacitance of a switched capacitor array, comprising:
a capacitor coupled between a switched capacitor array output and a node;
a switch coupled between the node and a first voltage source, the switch having a switch capacitance; and
a resistor coupled between the node and a second voltage source, for biasing the switch to reduce the switch capacitance.

2. The circuit of claim 1, wherein the switch control is coupled to a switched capacitor array input.

3. The circuit of claim 1, further comprising a second switch coupled between the resistor and the second voltage source.

4. The circuit of claim 3, wherein the second switch control is coupled to a switched capacitor array input.

5. The circuit of claim 3, wherein the second switch is a transistor.

6. The circuit of claim 1, further comprising a second switch coupled between the resistor and the node.

7. The circuit of claim 6, wherein the second switch control is coupled to a switched capacitor array input.

8. The circuit of claim 6, wherein the second switch is a transistor.

9. The circuit of claim 1, wherein the switch is a transistor.

10. The circuit of claim 1, wherein the switched capacitor array is part of at least one of a tank circuit, a tuned tank circuit, a voltage controlled oscillator, a processor, a transmitter, and a receiver.

11. A method for reducing capacitance of a switched capacitor array, comprising:
turning off a switch to reduce an energy flow in a capacitor in the switched capacitor array; and
biasing the switch to reduce a switch capacitance.

12. The method of claim 11, further comprising actuating a second switch to control the biasing.

13. The method of claim 11, wherein the switch capacitance is a drain to body capacitance.
